(19) United States
(12) Patent Application Publication
(10) Pub. No.: US 2011/0248870 A1
(43) Pub. Date: Oct. 13, 2011

(54) KEYPAD ASSEMBLY

(75) Inventor: Jae-Byeong HAN, Yongin-si (KR)

(73) Assignee: SAMSUNG ELECTRONICS CO. LTD., Suwon-si (KR)

(21) Appl. No.: 13/076,813

(22) Filed: Mar. 31, 2011

(30) Foreign Application Priority Data
Apr. 7, 2010 (KR) 10-2010-0031701

(51) Int. Cl. H03K 17/94

(52) U.S. Cl. 341/22

(57) ABSTRACT

A keypad assembly is provided. The keypad assembly includes a case frame, unit key blocks, and a main board. The case frame defines an outer surface. The unit key blocks are inserted into the case frame, arranged to be exposed from the case frame, and disposed at positions that are freely changeable. The main board is located under the unit key blocks, performs an event corresponding to a signal generated for the respective key blocks when the unit key blocks are pressed.

### PRIORITY

This application claims the benefit under 35 U.S.C. §119(a) of a Korean patent application filed in the Korean Intellectual Property Office on Apr. 7, 2010 and assigned Ser. No. 10-2010-0031701, the entire disclosure of which is hereby incorporated by reference.

### BACKGROUND OF THE INVENTION

1. Field of the Invention

The present invention relates to a keypad assembly of a mobile terminal More particularly, the present invention relates to a keypad assembly where a key arrangement can be freely rearranged.

2. Description of the Related Art

Currently, a mobile terminal has become a necessity of modern society and functions to transfer information that changes fast. The mobile terminal provides additional functions, is lightweight and has a slim profile.

Although the mobile terminal is lightweight and has a slim profile, the mobile terminal may not meet a user's various desires. More particularly, a mobile terminal with a key arrangement that is not suitable for personal use is inconvenient. For example, a conventional mobile terminal with a key arrangement that is advantageous for a right-handed user may be an inconvenience to a left-handed user.

### SUMMARY OF THE INVENTION

Aspects of the present invention are to address at least the above-mentioned problems and/or disadvantages and to provide at least the advantages described below. Accordingly, an aspect of the present invention is to provide a keypad assembly configured to meet a user's various diversified desires using one mobile terminal.

Another aspect of the present invention is to provide a keypad assembly in which keys can be freely rearranged.

Still another aspect of the present invention is to provide a keypad assembly for generating the same key event even when keys are rearranged.

In accordance with an aspect of the present invention, a keypad assembly is provided. The keypad assemble includes a case frame for defining an outer surface, unit key blocks inserted into the case frame, arranged to be exposed from the case frame, and disposed at positions that are freely changeable, and a main board, located under the unit key blocks, for generating signals discriminated for respective key blocks when the unit key blocks are pressed, and for performing an event corresponding to a generated signal.

In accordance with another aspect of the present invention, a keypad assembly is provided. The keypad assembly includes a case frame for defining an outer surface, unit key blocks inserted into the case frame, arranged to be exposed from the case frame, and disposed at positions that are freely changeable, each unit key block for causing different electrical contact points when pressed, and a main board for making a relevant open circuit a closed circuit using the electrical contact points caused by a corresponding unit key blocks to perform a corresponding event.

In accordance with still another aspect of the present invention, a keypad assembly is provided. The keypad assembly includes a case frame for defining an outer surface, unit key blocks inserted into the case frame, arranged to be exposed from the case frame, and disposed at positions that are freely changeable, each unit key block for outputting a different signal when pressed, and a main board for performing corresponding events according to signals output from the unit key blocks.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a view illustrating key arrangement in a mobile terminal to which a keypad assembly is applied according to an exemplary embodiment of the present invention;

FIG. 2 is a perspective view illustrating a separated keypad assembly according to an exemplary embodiment of the present invention;

FIG. 3 is a perspective view illustrating a unit key block of a keypad assembly according to an exemplary embodiment of the present invention;

FIG. 4 is a perspective view illustrating a coupled keypad assembly according to an exemplary embodiment of the present invention;

FIG. 5 is a perspective view illustrating a separated keypad assembly according to an exemplary embodiment of the present invention;

FIG. 6 is a perspective view and a partial cross-sectional view of a unit key block of a keypad assembly according to an exemplary embodiment of the present invention;

FIG. 7 is a perspective view illustrating a separated keypad assembly according to an exemplary embodiment of the present invention; and

FIG. 8 is a perspective view and a partial cross-sectional view of a unit key block of a keypad assembly according to an exemplary embodiment of the present invention.

Throughout the drawings, it should be noted that like reference numerals are used to depict the same or similar elements, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a”, “an”, and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

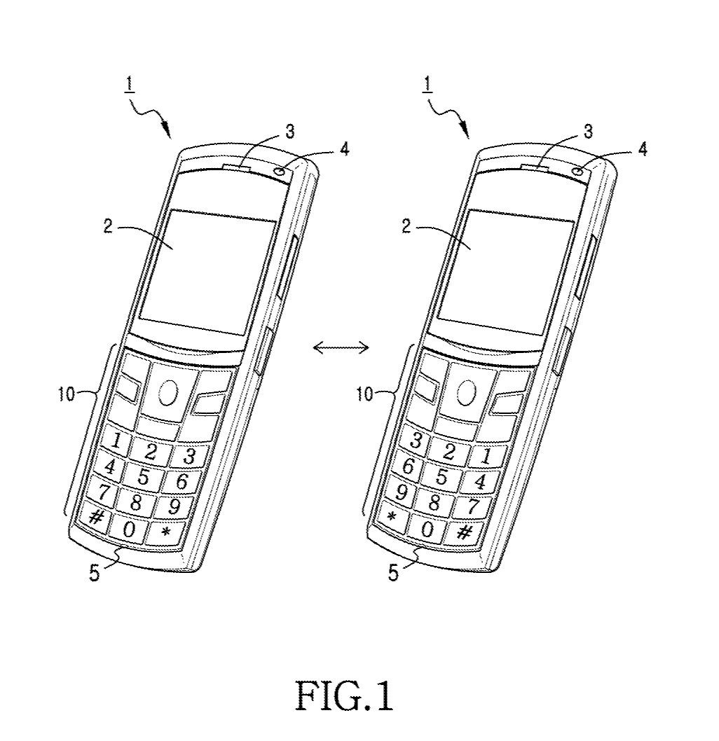

FIGS. 1 through 8, discussed below, and the various exemplary embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly stated otherwise. A set is defined as a non-empty set including at least one element.

Exemplary embodiments of the present invention provide a technology relating to a keypad assembly, more particularly, to a keypad assembly in which keys may be freely rearranged.

FIG. 1 is a view illustrating key arrangement in a mobile terminal to which a keypad assembly is applied according to an exemplary embodiment of the present invention.

Referring to FIG. 1, a display unit 2 is installed on a relevant position of a body of the terminal 1. The display unit 2 serves as a data output unit. The display unit 2 outputs data corresponding to manipulation of a keypad assembly 10 which will be described later, and displays various state information of the terminal 1. However, the display unit 2 is not limited thereto but when it is applied as a touch screen, it can also be used as a data input unit.

A speaker unit 3 for outputting a counterpart user's voice is installed on the upper portion of the display unit 2. A camera assembly 4 for capturing an object may be additionally installed on one side of the speaker unit 3. Furthermore, a microphone 5 for inputting voice is installed on the lower portion of the keypad assembly 10.

The keypad assembly 10 includes a plurality of numerical key blocks, control key blocks, and the like. The plurality of key blocks is inserted inside a case frame defining an outer surface of the mobile terminal 1. More particularly, as illustrated in FIG. 1, the key blocks may be selectively rearranged.

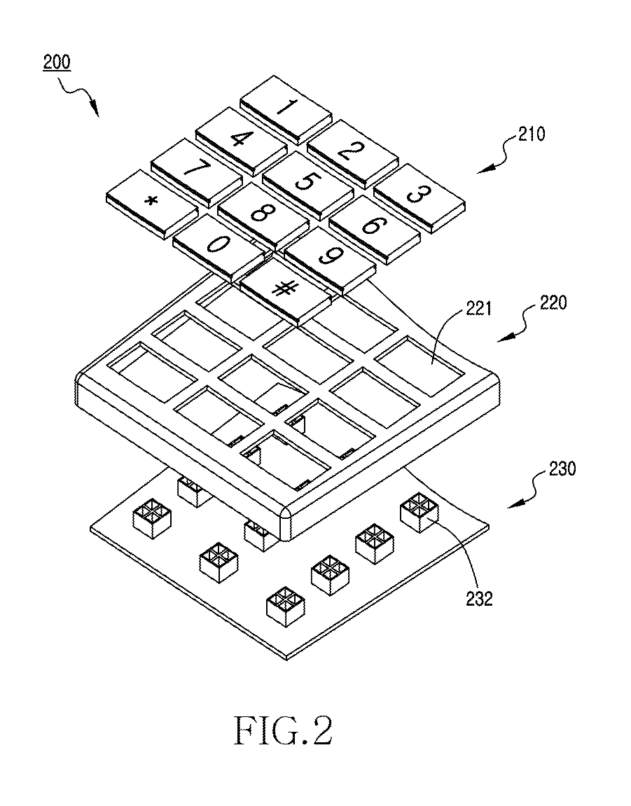

FIG. 2 is a perspective view illustrating a separated keypad assembly according to an exemplary embodiment of the present invention.

Referring to FIG. 2, the keypad assembly 200 includes a plurality of unit key blocks 210, a case frame 220 defining the outer surface and inserting the unit key blocks 210 therein, and a main board 230 for detecting a pressed relevant unit key block to perform a relevant operation.

The unit key blocks 210 are indexed and discriminated. In addition, the unit key blocks 210 are detachable from the case frame 220 and the main board 230. Furthermore, the unit key blocks 210 may be detached from the case frame 220 and the main board 230 and rearranged in a place of a different unit key block.

The case frame 220 includes a plurality of through holes 221 for inserting the unit key blocks 210 therein.

The main board 230 includes a switch unit 232 for fixing the unit key blocks 210, and the switch unit 232 may generate a signal when a relevant unit key block is pressed.

More particularly, the keypad assembly 200 generates the same event as the event before rearrangement even when the relevant unit key block is rearranged and pressed. For example, a unit key block that has been used for an event for moving a cursor to the left direction is used for the same event even when it is rearranged and changes its position. The construction thereof is described below in more detail.

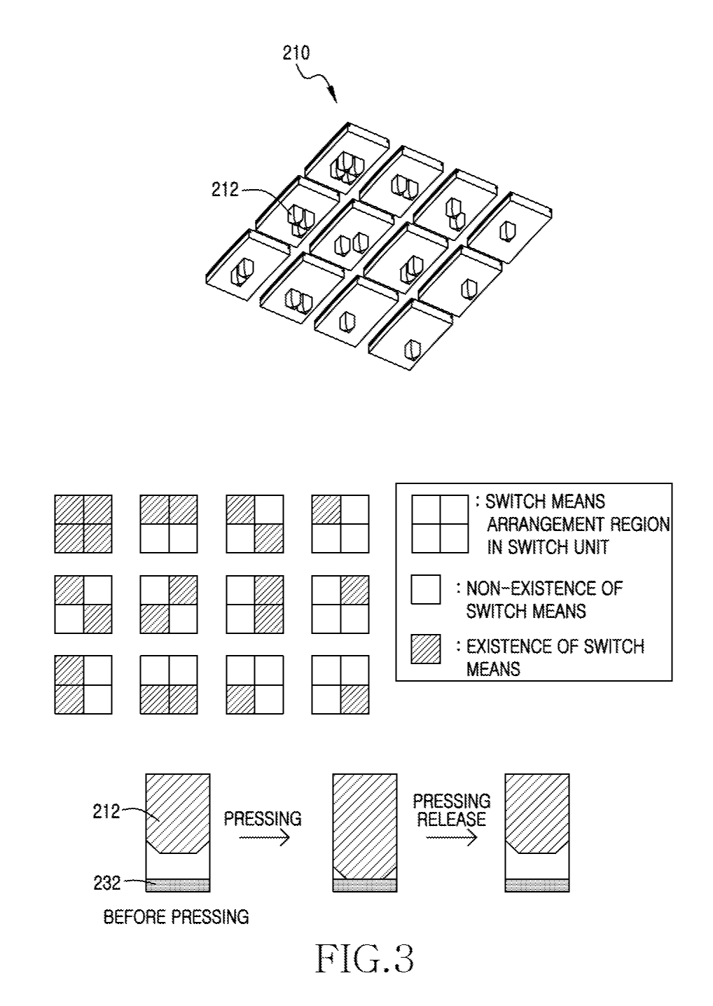

FIG. 3 is a perspective view illustrating a unit key block of a keypad assembly according to an exemplary embodiment of the present invention.

Referring to FIG. 3, the unit key blocks 210 are discriminated by a protrusion 212 arranged differently. The switch unit 232 may fix the unit key blocks 210 by receiving the protrusion 212. The switch unit 232 may include a switch means for generating a signal when pressed. The switch means may be one of a dome switch, a pressure sensor, and the like. The switch means is arranged to correspond to protrusions of all unit key blocks. For example, as illustrated, the switch means are arranged in four regions to correspond to four protrusions. When the protrusion 212 of the unit key block 210 presses the switch means of the switch unit 232, a signal is generated. Therefore, the switch unit 232 may generate signals from at least one means. The main board 230 may detect signals generated from the switch unit 232 to determine a unit key block having a relevant index (or protrusion), and may generate an event matching with the determined key block. In addition, the switch unit 232 may further include a return unit for automatically returning to an original position when the protrusion 212 of the unit key block 210 is pressed and released.

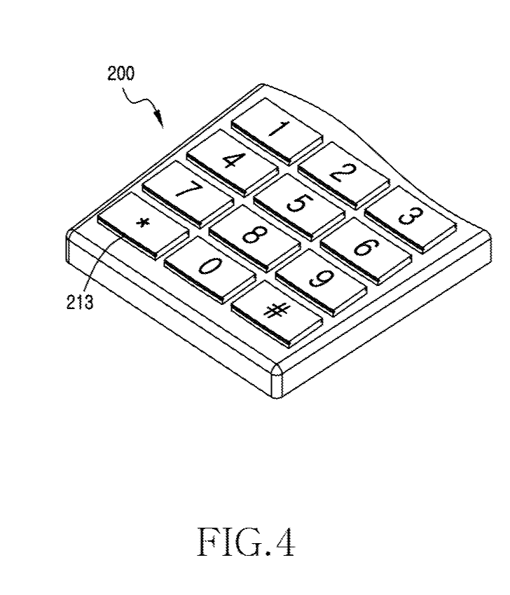

FIG. 4 is a perspective view illustrating a coupled keypad assembly according to an exemplary embodiment of the present invention.

Referring to FIG. 4, the key blocks 210 may include a chin 213 for facilitating detachment from the case frame 220. For example, a user may insert a nail to the chin 213 to grip the unit key block.

The exemplary embodiments of the present invention are the same in that the keypad assembly generates the same event as the event before rearrangement, even when a relevant key block is rearranged and pressed. Therefore, description thereof is omitted.

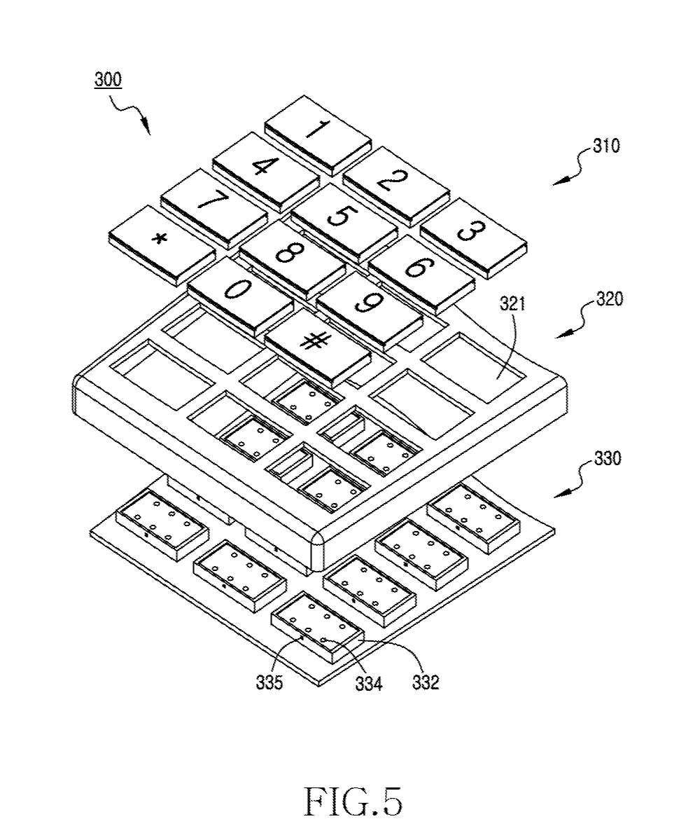

FIG. 5 is a perspective view illustrating a separated keypad assembly according to an exemplary embodiment of the present invention.

Referring to FIG. 5, the keypad assembly 300 includes a plurality of unit key blocks 310, a case frame 320 defining an outer surface and inserting the unit key blocks 310 therein, and a main board 330 for performing a relevant operation when relevant unit key blocks 310 are pressed.

The unit key blocks 310 are indexed and discriminated. In addition, the unit key blocks 310 are detachable from the case frame 320 and the main board 330. Furthermore, the unit key blocks 310 may be detached from the case frame 320 and the main board 330 and rearranged in a place of a different unit key block.

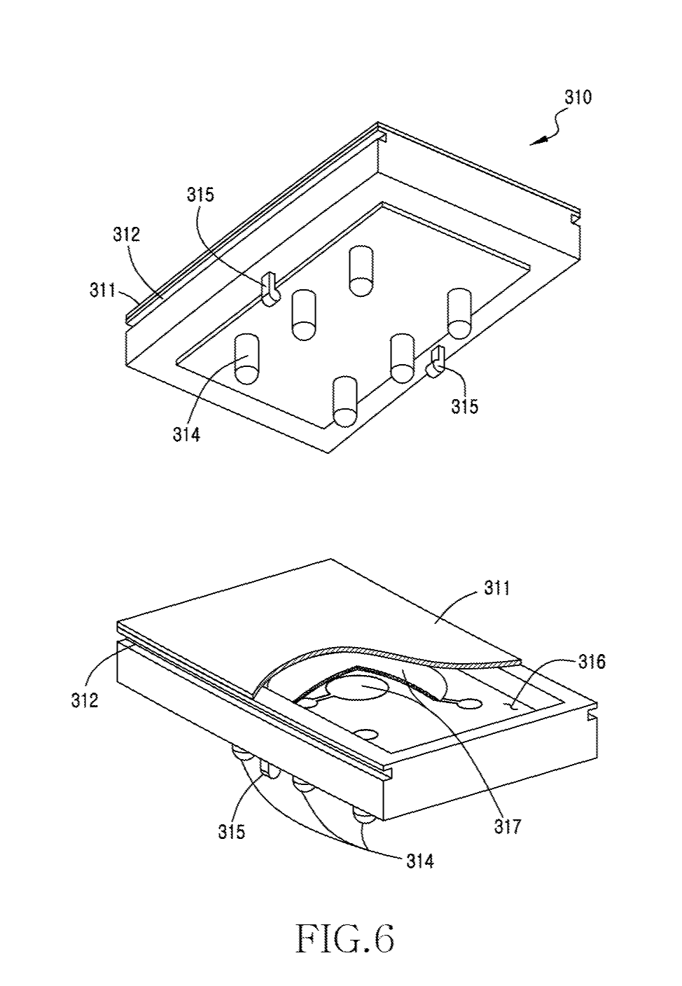

The unit key blocks 310 include a switch means for electrically connecting two insulated circuits when pressed. The unit key blocks 310 include a plurality of pins (314 illustrated in FIG. 6) in common on a lower portion. The pins 314 have an insulated circuit. Here, a switch means of any one unit key block is configured to connect a pair of different pins with a switch means of a different unit key block. Therefore, each unit key block 310 is discriminated by electrically connecting a pair of pins differently.

The case frame 320 includes a plurality of through holes 321 for inserting the unit key blocks 310 therein.

The main board 330 includes unit connectors 332 for binding the unit key blocks 310. The unit connector 332 has pin holes 334 for binding the pins (314 illustrated in FIG. 6) of the unit key block 310 in a socket. The pin holes 334 of any one pair is an open circuit until an electrical contact occurs at a switch means of the unit key block 310. That is, the pin holes 334 of any one pair make a designated closed circuit by allowing a current to flow through the switch means of the unit key block 310. The main board 330 has different open circuits (or closed circuits) discriminated for each unit block 310. Therefore, when a specific open circuit changes to a closed circuit, the main board 330 detects the changed closed circuit and controls to perform a preset event according to the relevant unit key block 310. That is, even when any one unit key block 310 is rearranged, the unit key block always maintains the designated open circuit (or closed circuit), thereby performing the same event.

In addition, the keypad assembly 300 may include a fixing means for coupling the connector 332 with the key block 310. The fixing means is easily detachable and may be one of screw coupling, snap fit coupling, and the like. As illustrated, the key block 310 and the connector 332 may couple through snap fit coupling. Accordingly, the key block 310 has a snap protrusion (315 illustrated in FIG. 6), and the connector 332 has a recess 335 corresponding to the snap protrusion 315.

FIG. 6 is a perspective view and a partial cross-sectional view of a unit key block of a keypad assembly according to an exemplary embodiment of the present invention.

Referring to FIG. 6, the unit key block 310 includes a plurality of pins 314 protruding to correspond to the pin holes 334 of the connector 332 (illustrated in FIG. 5). In addition, the unit key block 310 includes a housing 316 for receiving the switch means 317 and other elements, and a cover 311 for covering the housing 316.

As described above, each pin 314 has an insulated circuit. The switch means 317 of each unit key blocks 310 is configured to connect a different pair of circuits. Here, the switch means of the unit key block 310 electrically connects only one designated pair of pins. Therefore, the rest of pins and circuits connected thereto may be removed. However, they may be used as another fixing means formed by the pins 314 fitted in the pin holes 334 together with the above-described fixing means.

The switch means 317 may be one of a dome switch, a membrane switch, and the like that causes an electrical contact by being pressed. Therefore, the cover 311 of the unit key block 310 that is directly pressed may be formed of a flexible film.

In addition, the unit key block 310 may include a chin 312 for facilitating detachment from the connector 332. For example, a user may insert a nail to the chin 312 to grip the unit key block.

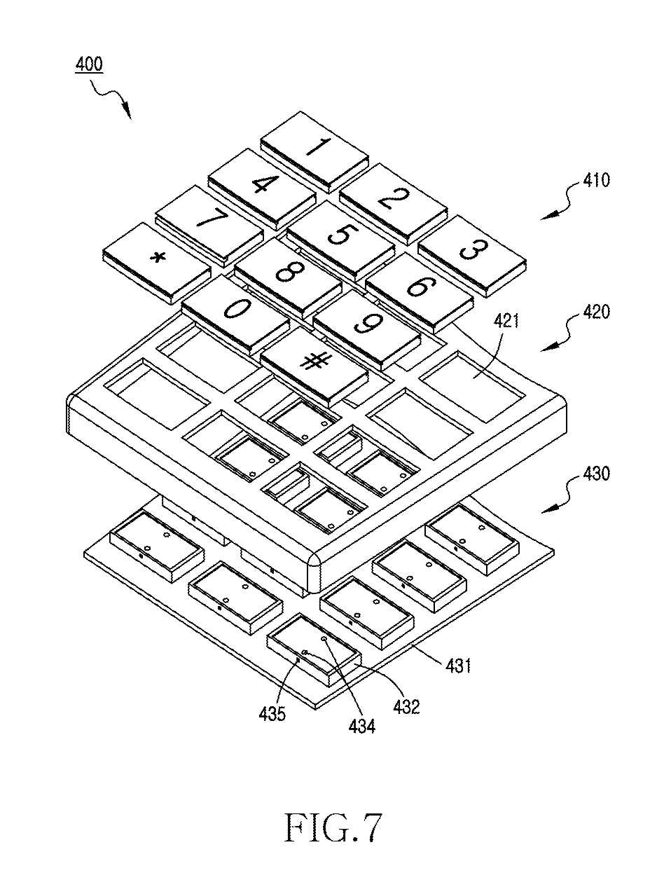

FIG. 7 is a perspective view illustrating a separated keypad assembly according to an exemplary embodiment of the present invention.

Referring to FIG. 7, the keypad assembly 400 includes a plurality of unit key blocks 410 for generating a signal when pressed, a case frame 420 defining outer surface and inserting the unit key blocks 410 therein, and a main board 430 for receiving a signal from the unit key blocks 410 to perform a relevant operation.

The unit key blocks 410 are indexed and discriminated. In addition, the unit key blocks 410 are detachable from the case frame 420 and the main board 430. Furthermore, the unit key blocks 410 may be detached from the case frame 420 and the main board 430 and rearranged in a place of a different unit key block.

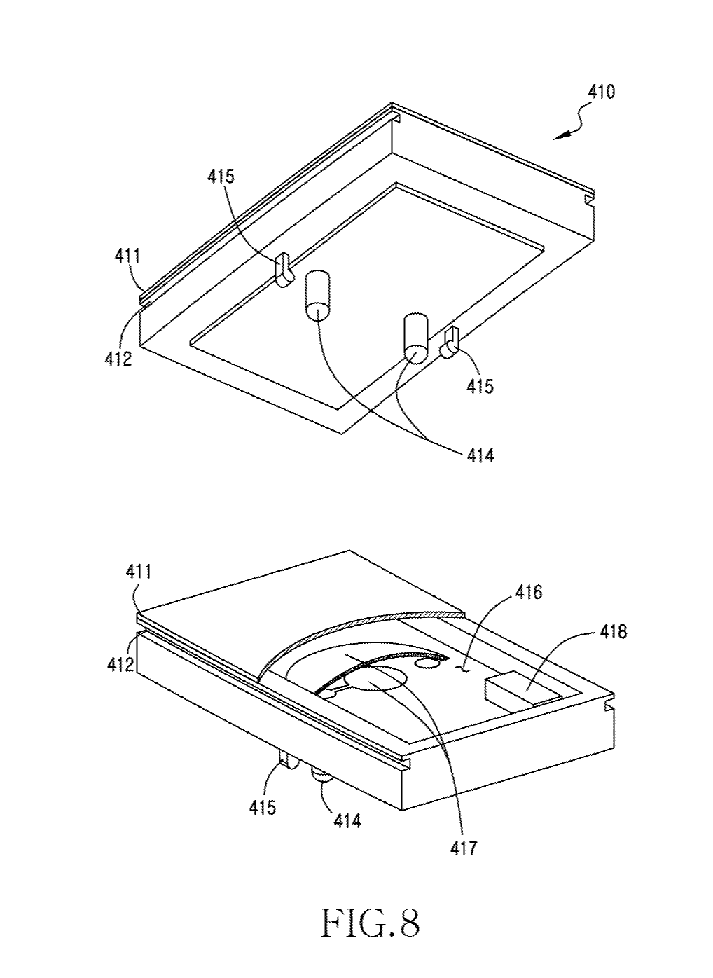

The unit key blocks 410 include a switch means (417 illustrated in FIG. 8) for electrically connecting two insulated circuits when pressed, and an input signal unit (418 illustrated in FIG. 8) for generating a relevant input signal when the two circuits are connected. When the two circuits are connected by the switch means 417, the input signal unit 418 may be driven by power of itself or the main board 430. For example, the input signal unit 418 may have a battery for driving. Alternatively, the input signal unit 418 may charge driving power of itself using a solar heat collector plate. Accordingly, the cover 411 of the unit key block may be utilized as the solar heat collector plate.

In addition, the unit key block 410 has pins (414 illustrated in FIG. 8) for transferring a signal generated from the input signal unit 418 to the main board 430. That is, each input signal unit of the unit key block 410 outputs a different signal.

The case frame 420 includes a plurality of through holes 421 for inserting the unit key blocks 410 therein.

The main board 430 includes connectors 432 for binding the unit key blocks 410 and receiving a signal generated from the unit key blocks 410. The connector 432 has pin holes 434 corresponding to a pin (414 illustrated in FIG. 8) of the unit key block 410. The pin holes 434 of each connector 433 are connected to a preset circuit of the main board 430. The main board 430 receives a signal generated from a relevant unit key block 410 through the pin holes 434 of a relevant connector 432. Thereafter, the main board 430 generates a relevant event according to a received signal. That is, each unit key block 410 outputs a different signal, and even when a relevant unit key block is rearranged, the relevant unit key block always provides the same signal to the main board, so that the same event may be generated.

Furthermore, the keypad assembly 400 may include a fixing means for connecting the connector 432 with the unit key block 410. The fixing means is easily detachable and may be one of a screw coupling, a snap fit coupling, and the like. As illustrated, the unit key block 410 and the connector 432 may couple through a snap fit coupling. The unit key block 410 has a snap protrusion (415 illustrated in FIG. 8), and the connector 432 has a recess 435 corresponding to the snap protrusion 415.

FIG. 8 is a perspective view and a partial cross-sectional view of a unit key block of a keypad assembly according to an exemplary embodiment of the present invention.

Referring to FIG. 8, the key block 410 includes pins 414 protruding downward. In addition, the key block 410 includes a switch means 417, the input signal unit 418, a housing 416 for receiving other elements, and a cover 411 for covering the housing 416.

The switch means 417 may be one of a dome switch, a membrane switch, and the like that causes an electrical contact by being pressed. Accordingly, the cover 411 of the unit key block 410 that is directly pressed may be formed of a flexible film.

In addition, the unit key block 410 may include a chin 412 for facilitating detachment from the connector 432. For example, a user may insert a nail to the chin 412 to grip the unit key block.

In describing FIGS. 2 to 8, the unit key block is configured to be fixed to a relevant main board and to operate. However, it is not limited thereto and the unit key block according to the exemplary embodiments of the present invention may be fixed to a case frame forming an appearance. More particularly, the unit key block has the return unit for returning after being pressed. Therefore, the return unit may cooperate with the unit key block in the case frame.

Consequently, the keypad assembly according to the exemplary embodiments of the present invention allows a key of the keypad to be rearranged and a proper key arrangement suitable for a user's tendency may be applied, so that use convenience of a mobile terminal increases.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A keypad assembly comprising:
a case frame for defining an outer surface;
unit key blocks inserted into the case frame, arranged to be exposed from the case frame, and disposed at positions that are freely changeable; and
a main board, located under the unit key blocks, for generating signals discriminated for respective key blocks when the unit key blocks are pressed, and for performing an event corresponding to a generated signal.

2. The keypad assembly of claim 1, wherein each of the unit key blocks comprises a uniquely arranged protrusion that enables the unit key blocks to be discriminated from each other when pressed against the main board, the main board comprises unit switch units corresponding to the unit key blocks, and the unit switch units generate a signal discriminated for each protrusion being pressed.

3. The keypad assembly of claim 2, wherein the unit switch units include a plurality of switch means for connecting two circuits via contact points when pressed, and the plurality of switch means are selectively pressed for each protrusion.

4. The keypad assembly of claim 3, wherein the unit key blocks return to their original positions when pressing is released.

5. The keypad assembly of claim 1, wherein the unit key blocks are pressed by being bound to the case frame or the main board.

6. A keypad assembly comprising:
a case frame for defining an outer surface;
unit key blocks inserted into the case frame, arranged to be exposed from the case frame, and disposed at positions that are freely changeable, each unit key block for causing different electrical contact points when pressed; and
a main board for making an open circuit a closed circuit using the electrical contact points caused by a corresponding unit key blocks to perform a corresponding event.

7. The keypad assembly of claim 6, wherein the unit key blocks each comprise at least one of a dome switch, a membrane switch, and a pantagraph switch that causes the electrical contact points.

8. The keypad assembly of claim 6, wherein the main board binds the unit key blocks, comprises unit connectors connected to a terminal of a plurality of open circuits, and connects the open circuit as a previous circuit when one of the unit key blocks is bound to a different unit connector.

9. The keypad assembly of claim 8, wherein the unit key blocks and the unit connectors are electrically connected through a pin coupling.

10. The keypad assembly of claim 6, wherein the unit key blocks are detachable from one of the case frame and the main board.

11. The keypad assembly of claim 6, wherein the unit key blocks are coupled to one of the case frame and the main board through a snap fit coupling.

12. A keypad assembly comprising:
a case frame for defining an outer surface;
unit key blocks inserted into the case frame, arranged to be exposed from the case frame, and disposed at positions that are freely changeable, each unit key block for outputting a different signal when pressed; and
a main board for performing corresponding events according to signals output from the unit key blocks.

13. The keypad assembly of claim 12, wherein the unit key blocks each comprise:
a switching means for electrically connecting an insulated circuit when pressed;
an input signal unit driven for outputting a set signal when the insulated circuit is electrically connected by the switching means; and
a medium means for transferring a signal generated from the input signal unit to the main board.

14. The keypad assembly of claim 13, wherein the input signal unit is driven by a replaceable battery.

15. The keypad assembly of claim 13, wherein the input signal unit is driven by a current generated from a solar collector plate provided to at least one side of the unit key blocks.

16. The keypad assembly of claim 13, wherein the switch means comprises at least one of a dome switch, a membrane switch, and a pantagraph switch.

17. The keypad assembly of claim 12, wherein the unit key blocks are detachable from one of the case frame and the main board.

18. The keypad assembly of claim 12, wherein the unit key blocks are coupled to one of the case frame and the main board through a snap fit coupling.

19. The keypad assembly of claim 13, wherein the medium means comprises at least one pin protruding downward, and the main board comprises a connector including a pin hole corresponding to the pin.
